(19) United States
(12) Patent Application Publication
(10) Pub. No.: US 2010/0058954 A1
(43) Pub. Date: Mar. 11, 2010

(54) Novel Carbon-Modified Photocatalyst Films and Method for Producing Same

(76) Inventor: Horst Kisch, Erlangen (DE)

Correspondence Address: Locke Lord Bissell & Liddell LLP;Attn: Michael Ritchie, Docketing, 2200 Ross Avenue, Suite # 2200, DALLAS, TX, 75201-6776, US

(21) Appl. No.: 12/555,326

(22) Filed: Sep. 8, 2009

(30) Foreign Application Priority Data
Sep. 9, 2008 (DE) 102008046391.4

(51) Int. Cl. C09D 7/12; C23C 16/44

(52) U.S. Cl. 106/285; 427/248.1; 427/255.11

(57) ABSTRACT

A novel carbon-modified titanium dioxide film (CMF-TiO₂) and a method for producing same by a CVD method at atmospheric pressure. The precursor compounds used in this context for the titanium dioxide and the carbon component are titanium-organic compounds and unsaturated aromatic hydrocarbons. Thermal treatment at about 250° C. to about 600° C., preferable at about 250° C. to about 300° C. forms a CMF-TiO₂, the carbon content of which is about 0.2% to about 10.0% by weight, preferably about 0.2% to about 6.0% by weight and particularly preferably about 0.2% to about 2.5% by weight. A CMF-TiO₂ film is characterised by high catalytic activity in the degradation of air and water pollutants with visible light and light absorption in the range from 400 nm to 700 nm, as well as by 1) a quasi-Fermi level of the electrons of −0.5 V at pH 7 (relative to NHE) and/or by 2) C1s bonding energies of 284.8, 286.3 and 288.8 eV; and/or by 3) an isotropic electronic spin resonance (ESR) signal at a g-value of 1.900 to 2.005.

### RELATED APPLICATION

This application claims priority to German patent application Serial No. DE 10 2008 046 391.4 filed Sep. 9, 2008.

### TECHNICAL FIELD OF THE INVENTION

The invention relates to novel thin, carbon-containing photocatalyst films based on titanium dioxide that are photoactive in the visible spectrum of daylight or artificial light and for methods of producing same, and more particularly to novel carbon-modified titanium dioxide films possessing photocatalytic activity when irradiated with light in the wavelength range from about 400 nm to about 700 nm and for methods of producing same.

### BACKGROUND OF THE INVENTION

Photocatalytic materials are semiconductors in which, when exposed to light, surface charges are formed that lead to the formation of reactive oxygen radicals in the presence of atmospheric oxygen and water vapor. It is generally known that these radicals are capable of completely oxidising (mineralising) pollutants in air and water to form environmentally friendly end products. Since the semiconductor itself remains unchanged in the process, it possesses photocatalytic activity. In the case of the frequently used titanium dioxide, irradiation with UV light is necessary to this end. In addition, the hydrophilicity of the titanium dioxide surface increases in the process, this leading to an anti-fogging effect of thin titanium dioxide films on mirrors and other objects.

One major disadvantage of titanium dioxide is the fact that it is only capable of utilising the UV component of sunlight, i.e. only 3% to 4% of the photochemically active radiation, meaning that it possesses only little or no catalytic activity in diffuse daylight. Consequently, intensive attempts have been made for some time to modify titanium dioxide in such a way that it can also develop photocatalytic activity by absorbing visible light, i.e. light with wavelengths of about 400 nm to about 700 nm, this corresponding to the major part of the photochemically usable sunlight.

To achieve this goal, thin titanium dioxide films doped with subgroup elements, such as chromium and vanadium, were produced on flat glass and other substrates, e.g. by means of chemical vapor deposition (“CVD”) (US 20030027000; Greenberg, Charles B., et al.). Only a few applications deal with the production of photoactive titanium dioxide films that contain carbon and are photoactive in the visible spectral range.

In one method, a titanium substrate, a titanium dioxide substrate or a titanium dioxide film on glass is brought directly into brief contact with a hydrocarbon or acetylene flame at 900° C. to 1500° C. According to XPS (X-ray photoelectron spectroscopy), the film obtained contains Ti—C bonds, as can be deduced from the C1s bonding energy value of 281.6 eV. The carbon content is in the region of 1.7 atom % to 8.0 atom % and the films catalyse the degradation of gaseous acetaldehyde with visible light (EP 1 693 479 A1, WO 2006 090 631).

In another method, a titanium dioxide film is first produced by sputtering and subsequently doped with carbon ions by means of an ion beam source. The film obtained in this way likewise contains Ti—C bonds, as concluded from XPS measurements (EP 1 606 110 A2).

A third method produces the carbon-containing film by pyrolysis of titanium-organic compounds, such as titanium alcoholates, at 350° C. to 700° C. In this case, the carbon originates from the alcohol substituent of the titanium compound (JP 2007 090 161 A). The resulting film contained from 3 to 7 weight percent carbon.

The disadvantage of the hitherto known methods summarised above is based on the fact not only that they require expensive and complicated apparatus, but also that the high process temperatures rule out the coating of temperature-sensitive substrates.

A need therefore arose for a method to produce carbon-modified titanium dioxide films (“CMF-TiO₂”) that operate at lower temperatures, preferably in the region of 250° C. to 300° C.

### SUMMARY OF THE INVENTION

The present invention is a carbon-modified titanium dioxide film (“CMF-TiO₂”) that can be applied to different substrates, including flat glass, metals and plastics, by a CVD method at temperatures of about 250° C. to about 600° C., preferably about 250° C. to about 300° C. and atmospheric pressure. The precursor compounds used in this context are titanium alcoholates, titanium halides and aromatic hydrocarbons. The novel CMF-TiO₂ film is characterised by high catalytic activity in the degradation of air and water pollutants with visible light and light absorption in the range from 400 nm to 700 nm, as well as by 1) a quasi-Fermi level of the electrons of −0.5 Vat pH 7 (relative to NHE) and/or by 2) C1s bonding energies of 284.8, 286.3 and 288.8 eV; and/or by 3) an isotropic electronic spin resonance (ESR) signal at a g-value of 1.900 to 2.005.

The new carbon-modified films of titanium dioxide (“CMF-TiO₂”) permit pollutant degradation both with direct and with diffuse daylight or artificial light and can be used to remove pollutants from air and water by means of absorption of visible light. The pollutants can be present in dissolved or gaseous form in this context.

Owing to the relatively low production temperature, a CMF-TiO₂ can be applied to a wide variety of substrates, preferably to glass, fibers, ceramics, concrete, building materials, SiO₂, metals and plastics. This results in diverse options for applications in branches of industry in which surfaces come into contact with polluted air or water, from the construction, to the automotive and to the environmental engineering industry.

When irradiated with visible light, a CMF-TiO₂ has a water contact angle of roughly 4° to 7°, whereas unmodified TiO₂ has a contact angle of roughly 24° to 25°. This light-induced increase in the hydrophilicity of the CMF-TiO₂ surface gives rise to further applications, such as non-fogging mirrors and windows.

Finally, a CMF-TiO₂ is also suitable for the photochemical production of hydrogen from water, owing to the more negative quasi-Fermi level of the electrons compared to electrochemical water reduction (−0.42 V, pH 7).

### BRIEF DESCRIPTION OF THE DRAWINGS

For a more complete understanding of the present invention and for further advantages thereof, reference is now made to the following description taken in conjunction with the accompanying drawings in which:

FIG. 1 is a graph showing the UV-Vis absorption spectrum of two films on glass. As can be seen, the CMF-TiO₂ (Example 1, 0.65% by weight carbon content, shown as a dashed line) displays significant light absorption in the visible range of the spectrum, in contrast to unmodified titanium dioxide (Comparative Example shown as a solid line);

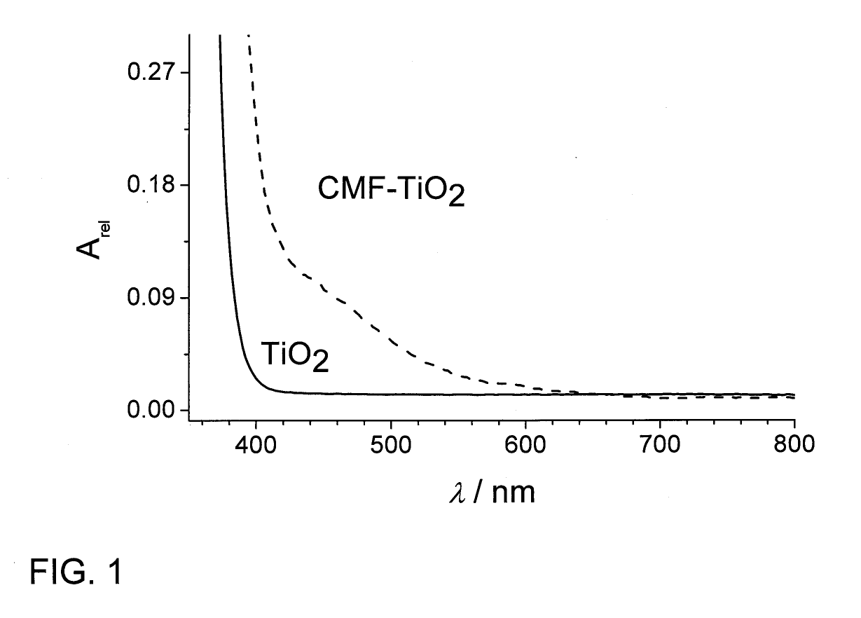

FIG. 2 is a graph showing the electron spin resonance (“ESR”) spectra of two CMF-TiO₂ samples with different carbon contents (prepared according to Example 1), measured at 5 K; the insert shows the spectra at 300 K. a) 1.02% by weight carbon content and b) 0.65% by weight carbon content;

FIG. 3 is a graph showing the X-ray photoelectron spectrum (“XPS”) of CMF-TiO₂ (Example 1, 0.65% by weight carbon content). The C1s bonding energies of b) 286.3 and c) 288.8 eV (relative to the signal of ubiquitous elemental carbon at 284.8 eV) indicate the presence of an aromatic carbon compound;

FIG. 4 is a graph showing the photovoltage as a function of the pH value. From the inflection point at pH about 6, the quasi-Fermi potential of the electrons of a CMF-TiO₂ sample (Example 1, 0.65% by weight carbon content) at pH 7 can be calculated as about −0.50 V (relative to NHE);

FIG. 5 is a graph showing the percentage degradation of benzene (5% by vol.), acetaldehyde (2% by vol.) and carbon monoxide (5% by vol.) by the diffuse daylight in a room (light intensity of approx. 0.4 mW/cm² over the range from 400 nm to 1,200 nm). The reaction vessel used is a 0.5-litre Erlenmeyer flask containing three CMF-TiO₂ glass plates (30×80 mm) (Example 1, 0.65% by weight carbon content). The top curve is obtained in the presence of a carbon-free titanium dioxide film (Comparative Example). The course of the reaction is monitored by infrared spectroscopic measurement of the carbon dioxide formed;

FIG. 6 is a graph showing the change in the TOC (“Total Organic Carbon”) value of an aqueous solution of 4-chlorophenol (2.5×10⁻⁴ M) when exposed to diffuse daylight in a room (light intensity of approx. 0.4 mW/cm² over the range from 400 nm to 1,200 nm). The reaction vessel used is a 50×100 mm Schlenk vessel containing a CMF-TiO₂ glass plate (30×80 mm) (Example 1, 0.65% by weight carbon content). In contrast to the carbon-free film (Comparative Example), the CMF-TiO₂ induces roughly 50% mineralisation after 6 hours; and

FIG. 7 is a schematic diagram of CVD equipment operating at atmospheric pressure. R: Reactor; H: Heater (heating plate, heating bath); S: Substrate (glass, metal, plastic, titanium dioxide film); V: Outlet valve; O: Oxygen source (water, alcohol); MP: Modifier precursor; TP: titanium dioxide precursor. Gas lines and washing bottles O, MP and TP can be heated, where appropriate.

### DESCRIPTION OF THE PREFERRED EMBODIMENTS

The method according to the invention can be performed according to two basic versions. The versions differ in that the carbon-containing film is produced in one step according to Method I and in two steps according to Method II.

### Method I

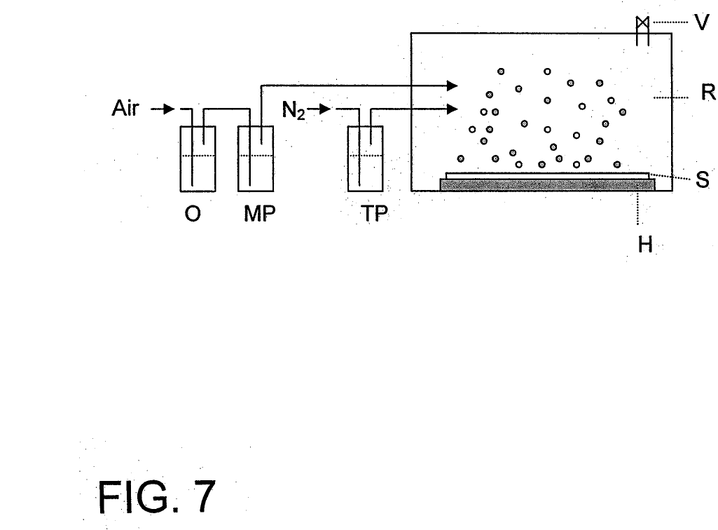

This method is a CVD process operating at atmospheric pressure, as schematically illustrated in FIG. 7. The precursor compounds used for the titanium dioxide component are organic titanium compounds or titanium halides, the precursor compounds for the modifying carbon component being aromatic hydrocarbons with suitable boiling points. By introducing air or N₂, the precursors are transported in gaseous form into the reaction chamber or reactor R, where they react on the hot substrate S to form a CMF-TiO₂. Substrate S can be glass, metal, plastic, or titanium dioxide film. Hot substrate S is located on heater H. Heater H can be a heating plate or heating bath. The substrate is heated to about 250° C. to about 600° C., preferably to about 250° C. to about 300° C. The film thickness and the carbon content of the films can be controlled by varying the boiling points of the precursors, the introduction rate and the temperature. If necessary, the process described can be preceded by application of a barrier layer, such as SiO₂, in order to prevent the potential diffusion of sodium and other ions from the substrate into the CMF-TiO₂. It is known that the photocatalytic activity of TiO₂ can be inhibited in this way. V is the outlet valve. O is the oxygen source (e.g., water, alcohol). MP is the modifier precursor. TP is the titanium dioxide precursor. Gas lines and washing bottles O, MP and TP can be heated, where appropriate.

### Method II

This version consists in an existing titanium dioxide film, produced by a process familiar in the art, being subsequently modified into a CMF-TiO₂ by the CVD method (Method I), omitting the titanium dioxide precursor.

In method I, the titanium dioxide precursors can be titanium alcoholates, titanium acetylacetonates and other organic titanium compounds with boiling points between 70° C. and 200° C. or titanium halides. In a preferred embodiment of Method I, titanium alcoholates with the general formula Ti(OR)₄ are used, where R stands for a straight-chain or branched alkyl residue with 2 to 4 carbon atoms. It is preferable for the residues (OR) in the above formula to be derived from oxo esters, β-diketones, carboxylic acids or keto alcohols, particularly preferably from acetylacetone. Examples of titanium alcoholates include Ti(OEt)₄, Ti(Oi-Pr)₄, Ti(On-Pr)₄ and Ti(acac)₂(Oi-Pr)₂.

Liquid aromatic hydrocarbons with suitable boiling points, such as toluene and xylene, are preferred as modifier precursors. However, mixtures of petroleum fractions with a high content of aromatic hydrocarbons can also be used.

A stream of air or nitrogen is used to introduce the precursor compounds into the reactor, where they react on the preheated substrate to form a CMF-TiO₂. Their boiling points and the introduction rates are selected in such a way that the CMF-TiO₂ film formed during the thermal treatment possesses the greatest possible photocatalytic activity and sufficiently high transparency. Where appropriate, small quantities of film-forming agents, such as acetylacetone, ethylenediamine and polyvalent alcohols, can be added to the precursor compounds.

The thermal treatment is preferably performed in such a way that the finished CMF-TiO₂ film exhibits a carbon content of about 0.2% to about 10.0% by weight, preferably about 0.2% to about 6.0% by weight, and particularly preferably about 0.2% to about 2.5% by weight. A CMF-TiO₂ is characterised in that it is photoactive in visible light.

The novel carbon-containing titanium dioxide films of the present invention preferably have light absorption in the range of λ>400 nm, and a quasi-Fermi potential of the electrons of about −0.50 V at pH 7 (relative to NHE). The novel carbon-containing titanium dioxide films of the present invention preferably have an isotropic electron spin resonance signal which occurs in the electron spin resonance spectrum at a g-value of about 1.900 to 2.005. The novel carbon-containing titanium dioxide films of the present invention preferably have C1s bonding energies of 284.8, 286.3 and 288.8 eV, referred to elemental carbon at 284.8 eV. The novel carbon-containing titanium dioxide films of the present invention preferably have an absorbance at 500 nm which is roughly 20% to 40% of the value at 400 nm. The novel carbon-containing titanium dioxide films of the present invention preferably have photoactivity in the degradation of pollutants with visible light (λ>400 nm). The novel carbon-containing titanium dioxide films of the present invention preferably have a carbon content of about 0.2% to about 10.0% by weight. The novel carbon-containing titanium dioxide films of the present invention preferably have a carbon content of about 0.2% to about 2.5% by weight.

### Examples

### Example 1

### Method I

A glass plate (substrate S) in the reactor chamber R (FIG. 7) is heated to 300° C. and maintained at this temperature. Water, toluene and titanium tetraisopropylate are subsequently filled into washing bottles O, MP and TP, respectively. Air is introduced through O and MP at a rate of 0.1 to 1.0 ml/min, nitrogen being introduced through TP at a rate of 1 to 10 ml/min. Depending on the nature of the glass surface, different reaction times are necessary to obtain an optimum film. This is achieved by corresponding variation of the introduction rate.

### Example 2

### Method II

Same procedure as in Example 1, the difference being that a glass plate S coated with an unmodified titanium dioxide film is used as the substrate.

### Example 3

Same procedure as in Example 1, the difference being that a substrate S made of a metal or a temperature-resistant non-metal is used instead of a glass plate.

### Example 4

Same procedure as in Example 2, the difference being that a substrate S made of a metal or a temperature-resistant non-metal is used instead of a glass plate.

### Comparative Example

Same procedure as in Example 1, the difference being that the toluene (MP) is omitted.

### Measuring Methods

a) Determination of the Photoactivity (Pollutant Degradation).

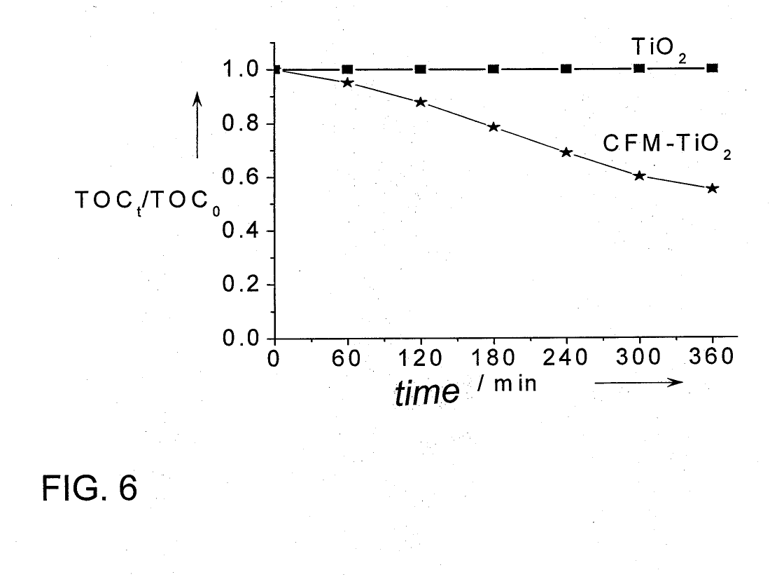

Degradation of 4-chlorophenol in water in the diffuse daylight of a room: In a 50×100 mm Schlenk vessel containing one CMF-TiO₂ glass plate (30×80 mm) a 2.5×10⁻⁴ molar aqueous solution of 4-chlorophenol is exposed to the diffuse daylight of a room (light intensity of approx. 0.4 mW/cm² over the range from 400 nm to 1000 nm). Mineralisation is monitored by measuring the total content of organic carbon (TOC value). In FIG. 6 the ratio of TOC₀ to TOCₜ, corresponding to the initial value and the value measured at time t, respectively, is plotted as function of irradiation time. In the case of the unmodified titania film (Comparative Example) this ratio stays constant whereas it decreases in the presence of CMF-TiO₂ (Example 1, 0.65% by weight carbon content) within 360 min by about 50%. The non-ideal shape of the degradation curve is due to fluctuations in room light intensity.

Degradation of acetaldehyde gas, benzene vapour and carbon monoxide in the diffuse daylight of a room:

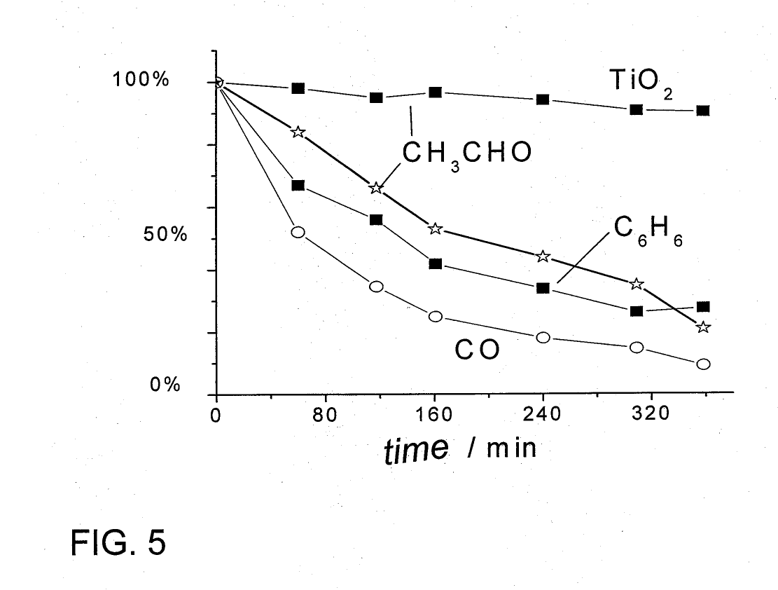

Air-saturated acetaldehyde gas (2% by vol.) or benzene vapor (5% by vol.) or carbon monoxide (5% by vol.) is filled into a 0.5-litre Erlenmeyer flask containing three CMF-TiO₂ glass plates (30×80 mm). The flask is then exposed to daylight in the laboratory, and the formation of carbon dioxide measured by IR spectroscopy. FIG. 5 summarizes some typical degradation measurements. Whereas the unmodified film (Comparative Example) causes only an insignificant concentration change of acetyldehyde gas, a decrease of about 70% is observed after 320 min irradiation time for CMF-TiO₂ (Example 1, 0.65% by weight carbon content). Corresponding values of 75% and 90% are observed for benzene and carbon monoxide pollutants, respectively, using CMF-TiO₂ (Example 1, 0.65% by weight carbon content). The non-ideal shape of the degradation curves is due to fluctuations in room light intensity

b) Determination of the Carbon Content

The carbon content is determined as the total organic carbon (“TOC”) content, using the LECO C-200 carbon analyser. The measuring method is based on incineration of the organic substance contained in the TiO₂ in the induction furnace under oxygen gas and subsequent determination, by means of IR detection, of the carbon dioxide forming. The sample used was the powder obtained by grinding CMF-TiO₂ glass by means of a ball mill.

c) XPS Measurements

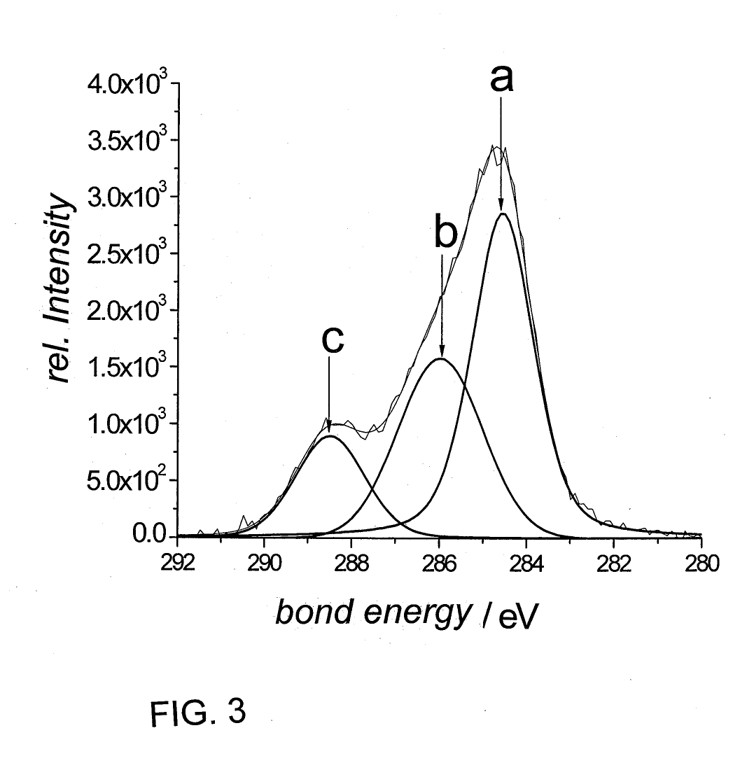

A Phi 5600 ESCA spectrometer (pass energy of 23.50 eV; Al standard; 300.0 W; 45.0°) was used to measure the bonding energies. All values are given relative to the signal of ubiquitous elemental carbon observed at 284.8 eV. As can be seen in FIG. 3 (Example 1, 0.65% by weight carbon content) the most intense peak is located at this bond energy. According to standard deconvolution methods two other peaks are present at 286.3 eV and 288.8 eV, assignable to carbon atoms of an aromatic hydrocarbon compound. It was surprisingly discovered that use of an aromatic hydrocarbon compound allows the CMF-TiO₂ to achieve an effective visible light photocatalyst with less than a 3% carbon content, likely due to the presence of unsaturated bonding as shown in FIG. 3.

d) ESR Measurements.

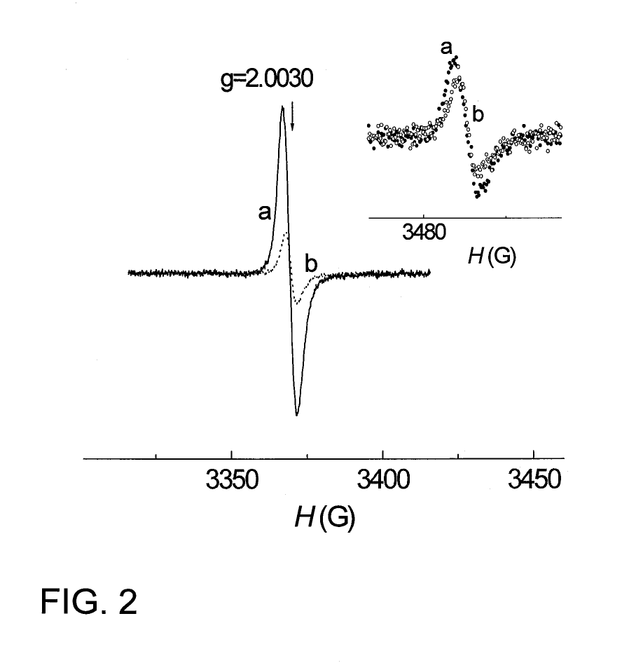

ESR spectra were measured with a Bruker Elexsys-580 ESR spectrometer (X-band, 100 kHz modulation frequency). Magnetic field modulated with 100 Hz. RF power: 0.0002 to 1 mW. Field: 3340 to 3500 G. Sweep width: 100 to 500 G. Conversion time: 81.92 ms. Time constant: 40.96 ms. Modified amplitude: 0.2 to 13 G. The standard used was Mn²⁺ in MgO. The samples were produced by first preparing thick films according to Example 1 on a glass substrate and then grinding them in a ball mill. The resultant powders were filled into quartz tubes, which were then filled with helium and sealed. From FIG. 2 it can be seen that both at temperatures of 5 K and 300 K the same symmetrical signal is observed. The higher intensity of the CMF-TiO₂ sample having the higher carbon content of 1.02% as compared to that having 0.65% (both samples prepared according to Example 1) indicates that the paramagnetic species is a carbon compound. Most likely it is an aromatic hydrocarbon as suggested by the g-value of 2.0030.

e) Determination of the Quasi-Fermi Potential

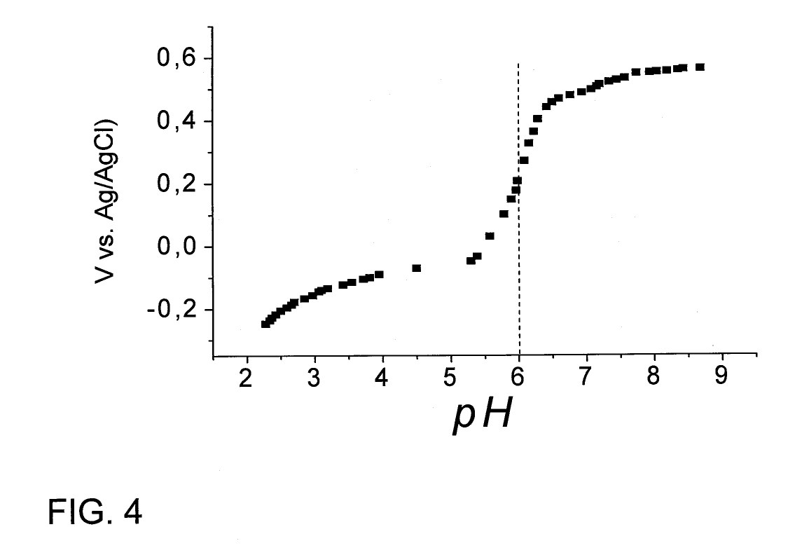

The quasi-Fermi potential was measured on a CMF-TiO₂ film on glass. To this end, the glass plate (30×80 mm) is dipped, in a 50 ml Schlenk flask and in the absence of air, in 0.1 M KNO₃ solution that additionally contains 50 mg methyl viologen dichloride and an Ag/AgCl and platinum electrode as the reference and working electrode. Concentrated HNO₃ is added to set a pH value of 2, and an Osram XBO 150 W lamp is used for exposure. A voltmeter (4035 multimeter from Messrs. Soar) is used to measure the change in the photovoltage while adding 0.1 M NaOH in portions. The inflection point of the titration curve obtained can be used to calculate the quasi-Fermi potential of the electrons (Roy, A. M.; De, G. C.; Sasmal, N.; Bhattacharyya, S. S. Int. J. Hydrogen Energy 20 (1995) 627). As evidenced from FIG. 4 the inflection point is located at about pH=6.0, from which the quasi-Fermi level of electrons is obtainable as about −0.50 V. This value describes the reduction potential of light-generated electrons located at the CMF-TiO₂ surface (Example 1, 0.65% by weight carbon content). It is negative enough providing a high driving force for reduction of aerial oxygen, the crucial primary step in the oxidation of pollutants.

f) Hydrophilic Properties

The contact angle of water was measured on a glass plate coated with a CMF-TiO₂. (Example 1, 0.65% by weight carbon content). It was 25° before and 7° after storage in daylight for six hours. This strong decrease indicates the light induced generation of a more hydrophilic CMF-TiO₂ surface, the basic property for the construction of antifogging materials.

1. A method for producing a carbon-modified film containing titanium dioxide comprising:
Imposing a substrate over a heating element in a reaction chamber;
Introducing into said reaction chamber an oxygen source, a modifier precursor comprising an aromatic hydrocarbon and a titanium dioxide precursor; and
Forming by chemical vapor deposition a film on said substrate having a carbon content of from about 0.2% to about 2.5%.

2. The method of claim 1 comprising imposing a barrier layer on said substrate prior to the introduction into said reaction chamber of an oxygen source, a modifier precursor and a titanium dioxide precursor.

3. The method of claim 2 wherein the barrier layer is SiO₂.

4. The method of claim 1 wherein said oxygen source, modifier precursor and titanium dioxide precursor are introduced into said reaction chamber by air in gaseous form.

5. The method of claim 1 wherein said oxygen source, modifier precursor and titanium dioxide precursor are introduced into said reaction chamber by N₂ in gaseous form.

6. The method of claim 1 wherein the substrate is glass, metal, plastic, or titanium dioxide film.

7. The method of claim 1 wherein the heating element is a heating plate or a heating bath.

8. The method of claim 1 wherein the oxygen source is water or alcohol.

9. The method of claim 1 wherein the aromatic hydrocarbon serving as the modifier precursor is toluene, xylene or a mixture thereof.

10. The method of claim 1 wherein the titanium dioxide precursor is a titanium alcoholate.

11. The method of claim 1 wherein the reaction is carried out at atmospheric pressure.

12. A carbon-containing titanium dioxide film produced by the method of claim 1 having light absorption in the range of λ≧400 nm and a quasi-Fermi potential of the electrons of about −0.50 V at pH 7 (relative to NHE).

13. A carbon-containing titanium dioxide film produced by the method of claim 1, wherein an isotropic electron spin resonance signal occurs in the electron spin resonance spectrum at a g-value of about 1.900 to 2.005.

14. A carbon-containing titanium dioxide film produced by the method of claim 1 having C1s bonding energies of 284.8, 286.3 and 288.8 eV, referred to elemental carbon at 284.8 eV.

15. A carbon-containing titanium dioxide film produced by the method of claim 1 wherein the absorbance at 500 nm is roughly 20% to 40% of the value at 400 nm.

16. A carbon-containing titanium dioxide film produced by the method of claim 1 wherein there is photoactivity in the degradation of pollutants with visible light (λ≧400 nm).

17. The method according to claim 1 wherein:
the titanium dioxide precursor compounds used are titanium alcoholates, titanium acetylacetonates and other organic titanium compounds with boiling points between about 70° C. and about 200° C., preferably titanium alcoholates of the general formula Ti(OR)₄, where R stands for a straight-chain or branched alkyl residue with 2 to 4 carbon atoms.

18. The method according to claim 1, wherein said aromatic hydrocarbon comprises an
unsaturated aromatic carbon compound with a boiling point between about 70° C. and about 200° C.

19. The method according to claim 18, wherein:
the aromatic carbon compound consists of toluene, xylene or a mixture of petroleum fractions with a high content of aromatic hydrocarbons.

20. The method according to claim 1, wherein said substrate is a flat glass emerging from a furnace during flat-glass production forms a substrate for the film.

21. The method according to claim 1, wherein:
the temperature of the substrate to be coated is about 250° C. to about 600° C.

22. The method according to claim 21, wherein:
the temperature of the substrate to be coated is about 250° C. to about 300° C.

23. A method for producing a carbon-modified film containing titanium dioxide comprising:
Imposing a substrate over a heating element in a reaction chamber;
Imposing a titanium dioxide film over said substrate;
Introducing into said reaction chamber an oxygen source and a modifier precursor comprising an aromatic hydrocarbon; and
Modifying by chemical vapor deposition said film on said substrate such that the carbon content is from about 0.2% to about 2.5%.

24. The carbon-containing titanium dioxide film formed by the method of claim 23 having light absorption in the ranges of λ≧400 nm and a quasi-Fermi potential of the electrons of about −0.50V at pH 7 (relative to NHE).

25. The method of claim 23 comprising: applying said modified film as a coating for metallic and non-metallic materials.

26. The method of claim 23 comprising: applying said modified film as a coating on air-conditioning equipment.

27. The method of claim 23 comprising: applying said modified film as a coating for water purification equipment.

28. A carbon-containing titanium dioxide film comprising an aromatic hydrocarbon, having a carbon content of from about 0.2% to about 2.5% and having light absorption in the range of λ≧400 nm, and a quasi-Fermi potential of the electrons of about −0.50 V at pH 7 (relative to NHE).

29. A carbon-containing titanium dioxide film comprising an aromatic hydrocarbon, having a carbon content of from about 0.2% to about 2.5% and wherein an isotropic electron spin resonance signal occurs in the electron spin resonance spectrum at a g-value of about 1.900 to 2.005.

30. A carbon-containing titanium dioxide film comprising an aromatic hydrocarbon, having a carbon content of from about 0.2% to about 2.5% and having C1s bonding energies of 284.8, 286.3 and 288.8 eV, referred to elemental carbon at 284.8 eV.
